(19) United States
(12) Patent Application Publication
(10) Pub. No.: US 2025/0030219 A1
(43) Pub. Date: Jan. 23, 2025

(54) LASER COMPONENT AND METHOD FOR PRODUCING A LASER COMPONENT

(71) Applicant: ams-OSRAM International GmbH, Regensburg (DE)

(72) Inventors: Tobias HAUPELTSHOFER, Breitenbrunn (DE); Markus Reinhard HORN, Bayerbach Bei Ergoldsbach (DE); Christoph WALTER, Regensburg (DE)

(73) Assignee: ams-OSRAM International GmbH, Regensburg (DE)

(21) Appl. No.: 18/713,811

(22) PCT Filed: Nov. 28, 2022
(86) PCT No.: PCT/EP2022/083449

§ 371 Date: May 28, 2024

(30) Foreign Application Priority Data
Dec. 2, 2021 (DE) 10 2021 131 795.9

(51) Int. Cl. H01S 5/0233; H01S 5/0239; H01S 5/40

(52) U.S. Cl. CPC H01S 5/0233; H01S 5/0239; H01S 5/4087

(57) ABSTRACT

The invention relates to a laser component including a first laser chip with a first emission region, a second laser chip with a second emission region, and a connection carrier with an upper side and an underside, wherein the first laser chip is secured to the upper side of the connection carrier and is electrically connected, the second laser chip is secured to the underside of the connection carrier and is electrically connected, and the connection carrier has a thickness of max. 200 μm.

### CROSS-REFERENCE TO RELATED APPLICATIONS

The present application is a national stage entry from International Application No. PCT/EP2022/083449, filed on Nov. 28, 2022, published as International Publication No. WO 2023/099391 A1 on Jun. 8, 2023, and claims priority to German Patent Application No. 10 2021 131 795.9, filed Dec. 2, 2021, the disclosures of all of which are hereby incorporated by reference in their entireties.

### FIELD

The invention relates to a laser component. The invention further relates to a method for producing a laser component.

### BACKGROUND

One object to be achieved is to specify a laser component that is particularly compact. Another object to be achieved is to specify a method for producing such a laser component.

A laser component is specified. The laser component is configured to emit light, in particular visible light, during operation. For example, the laser component can be configured to emit colored light and/or white light during operation.

### SUMMARY

According to at least one embodiment, the laser component comprises a first laser chip having a first emission region. The first laser chip is an edge-emitting semiconductor laser chip, for example. The edge-emitting semiconductor laser chip emits light, in particular visible light, during operation.

Light is emitted during operation in the emission region of the first laser chip, the first emission region. The first emission region can comprise one, two or more emitters. Light is emitted from each emitter during operation of the first laser chip. In particular, it is possible for all emitters in the first emission region to emit light with the same peak wavelength. The emitters of the first emission region are arranged next to each other in a lateral direction, for example. The lateral direction is, for example, a direction that runs parallel to a main extension plane of the laser component.

According to at least one embodiment, the laser component comprises a second laser chip having a second emission region. The second laser chip is an edge-emitting semiconductor laser chip, for example. The second emission region of the second laser chip comprises one, two or more second emitters. During operation, the second laser chip emits light, preferably with a peak wavelength that is different from the peak wavelength of the light emitted by the first laser chip during operation. This means, for example, that the first laser chip and the second laser chip can emit light of different colors during operation.

According to at least one embodiment of the laser component, the laser component comprises a connection carrier having an upper side and a lower side. The connection carrier is in the form of a plate or disk, for example, which has a thickness in the vertical direction that is small compared to the extension of the connection carrier in lateral directions. The connection carrier is, for example, cuboid in shape.

The connection carrier can comprise a base body that is formed with an electrically insulating material. Metallizations are applied in and/or on the connection carrier, serving as contacts and/or via connections through the connection carrier.

According to at least one embodiment of the laser component, the first laser chip is attached and electrically connected to the upper side of the connection carrier. This means that there is a mechanically fixed connection between the connection carrier and the first laser chip, which is not detachable in a non-destructive manner, for example. Not detachable in a non-destructive manner means, for example, that one or both elements are destroyed when the connection is detached. The connection carrier is the mechanically supporting element, at least for the first laser chip. In addition, the connection carrier is used for electrical contacting of the first laser chip.

According to at least one embodiment of the laser component, the second laser chip is attached and electrically connected to the lower side of the connection carrier. In this way, the connection carrier can also represent a mechanically supporting element or the mechanically supporting element for the second laser chip. The second laser chip can also be connected to the connection carrier such that it is not detachable in a non-destructive manner. The second laser chip can be contacted electrically via the connection carrier. The first laser chip and the second laser chip are therefore located on two different sides of the connection carrier.

According to at least one embodiment of the laser component, the connection carrier has a thickness of at most 200 μm. In particular, the connection carrier has a thickness of at most 150 μm, preferably of less than 150 μm. With such a thin connection carrier, it is possible to arrange the laser chips particularly close to each other. In this way, the laser component can be made particularly compact, for example.

According to at least one embodiment of the laser component, the laser component comprises a first laser chip having a first emission region, a second laser chip having a second emission region, and a connection carrier having an upper side and a lower side. The first laser chip is attached and electrically connected to the upper side of the connection carrier, the second laser chip is attached and electrically connected to the lower side of the connection carrier, and the connection carrier has a thickness of at most 200 μm.

A laser component described here is based on the following considerations, among others. The use of laser components close to the human eye requires laser components with the smallest possible base area in order to be able to wear the laser component on the head, for example in AR glasses. It proves to be particularly advantageous if the emission regions of the laser chip of the laser component can be arranged particularly close to each other, for example in order to be able to use the same optics for the light of all laser chips of the laser component. The laser component described here is based on the idea of attaching different laser chips to different sides of a connection carrier designed particularly thin. This allows the emission regions of the different laser chips to be arranged particularly close to each other.

According to at least one embodiment of the laser component, the laser component comprises a third laser chip having a third emission region. The third laser chip may be an edge-emitting semiconductor laser chip. The third laser chip comprises an emission region which can comprise one or more third emitters, through which the electromagnetic radiation generated in the third laser chip leaves the laser chip during operation of the laser component. During operation, the third laser chip preferably generates light, in particular visible light, which has a peak wavelength that is different from the peak wavelengths of the light generated by the first laser chip and the second laser chip during operation. For example, the laser chips of the laser component generate light of different colors in pairs.

The third laser chip can be attached and electrically connected to the upper side or the lower side of the connection carrier. This means that the third laser chip is also mechanically supported by the connection carrier and is connected to it such that it is not detachable in a non-destructive manner, for example. Furthermore, the third laser chip can also be contacted electrically via the connection carrier.

This makes it possible, for example, to mount a laser chip that emits red light during operation, a laser chip that emits green light during operation and a laser chip that emits blue light during operation as close together as possible. Two of the laser chips are mounted on one side of the connection carrier and the third laser chip is mounted on the other side of the connection carrier.

According to at least one embodiment of the laser component, the laser component comprises at least one further laser chip having at least one further emission region, wherein the at least one further laser chip is attached and electrically connected to the upper side or the lower side of the connection carrier. It is possible, for example, that the laser component comprises four or more laser chips with, for example, two laser chips having the same peak wavelength but different LIV characteristics or power ranges.

According to at least one embodiment of the laser component, the light emitted by the laser chips, for example by the first laser chip, the second laser chip and the third laser chip, during operation can be mixed to form white light. In other words, the laser chips are selected in such a way that an operating state of the laser component is possible in which the light emitted by the three or more laser chips during operation mixes to form white light in the far field.

According to at least one embodiment of the laser component, the first, second and third laser chips are each attached to the connection carrier at their respective top surface, with the first, second and third emission regions being arranged closer to the respective top surface than to the bottom surface of the laser chips opposite the top surface.

This means that each laser chip has a top surface and a bottom surface opposite the top surface. The emission regions of each laser chip are arranged closer to its top surface than to its bottom surface. The laser chips are then attached to the connection carrier in such a way that the top surface faces the connection carrier.

For example, the top surface is always the p-side of the associated laser chip. In the event that one laser chip is attached to the upper side of the connection carrier and two laser chips are attached to the lower side of the connection carrier, one laser chip is therefore mounted with the p-side facing down (p-down) and the other two laser chips are mounted with the p-side facing up (p-up).

In this way, it is possible to place the emission regions of the individual laser chips as close as possible to the connection carrier. Due to the fact that the connection carrier has a thickness of at most 200 μm, the emission regions of the laser chips mounted on the upper side and the lower side of the connection carrier are arranged particularly close to each other. In particular, this makes it possible to mount the emission regions closer to each other also in the lateral direction than is possible when three laser chips are mounted laterally next to each other.

Overall, this creates the smallest possible light emission window. Also, possible differences in the height of the semiconductor laser chips do not play a role, as the laser chips are each attached to the connection carrier with the side closest to the emission region.

According to at least one embodiment of the laser component, the connection carrier comprises glass, ceramic material, plastic, silicon and/or diamond or is made of one of these materials. Such a connection carrier can be made particularly thin. In particular, it is possible with these materials to realize connection carriers that have a thickness of less than 150 μm, in particular 100 μm or less. Nevertheless, the materials have good heat conductivity. The connection carrier can comprise a base body that is designed accordingly. Furthermore, it is possible that the connection carrier comprises a base body which is formed with an electrically insulating material and which is covered with an electrically insulating layer. The electrically insulating layer can be formed with the aforementioned materials, for example.

According to at least one embodiment of the laser component, the first, second and third emission regions are each arranged on a front side of the connection carrier. This means that the three emission regions of the three laser chips are oriented in the same direction. It is possible that the facets of the laser chips, which comprise the emission regions, are arranged parallel to each other and parallel to the front side of the connection carrier. Furthermore, the facets and thus the first, second and third emission regions can lie in a common plane. It is also possible for the laser chips to protrude beyond the front side of the connection carrier. This allows a particularly large proportion of the surface of the connection carrier to be used for contacting the laser chips.

According to at least one embodiment of the laser component, two of the laser chips protrude laterally beyond the connection carrier. For example, two laser chips are arranged on one side of the connection carrier. These laser chips protrude beyond the connection carrier on opposite side surfaces in a lateral direction. In other words, in this embodiment, the connection carrier does not completely cover the two laser chips, but only partially. This makes it possible to use a particularly small connection carrier which, in addition to its low thickness, also has a small surface area. In this way, even expensive materials such as diamond can be used economically to form the laser component.

According to at least one embodiment of the laser component, an optical element is arranged downstream of the first, second and third laser chips in such a way that the light generated by the laser chips during operation passes through the optical element in each case. For example, due to the fact that the emission regions of the laser chips can be arranged particularly close to each other, it is possible to use the same optical element for the light of the laser chips. This allows a particularly compact laser component to be generated.

According to at least one embodiment of the laser component, the laser component comprises a module carrier, to which two of the laser chips are attached on their side facing away from the connection carrier. The module carrier can be the mechanically supporting element of the laser component, which, in addition to the laser chip attached to it, also mechanically supports the connection carrier and the laser chip attached to the latter. The module carrier can also be used for electrical contacting of the laser component. Furthermore, an optical system can be attached to the module carrier, for example.

According to at least one embodiment of the laser component, the connection carrier is the only supporting element of the laser component. This means that in this case all elements of the laser component are mechanically supported by the connection carrier and the connection carrier is the only supporting element to which, for example, the first laser chip, the second laser chip, the third laser chip and/or possibly further laser chips are mechanically connected. In this case, the laser component can in particular also be free of other supporting elements such as a heat sink and/or a module carrier.

Further, a method for producing a laser component is specified. In particular, the method can be used to produce a laser component as described herein. This means that all the features described for the laser component are also disclosed for the method for producing a laser component and vice versa.

According to at least one embodiment of the method, a module carrier plate is first provided. The module carrier plate is, for example, cuboid in shape and has a thickness that is small compared to the lateral extension of the module carrier plate.

A plurality of second laser chips and third laser chips are applied on the module carrier plate. The laser chips can, for example, be permanently attached to the module carrier plate, or the module carrier plate is only intended as a temporary carrier. In this case, the second and third laser chips can be detached from the module carrier plate non-destructively after the method has been completed.

In a next method step, a connection carrier plate is applied on the second laser chips and the third laser chips on their side facing away from the module carrier plate. The connection carrier plate is also cuboid in shape, for example, and has a base area that can correspond to the base area of the module carrier plate.

In a next method step, the connection carrier plate is thinned to a target thickness. The connection carrier plate can be thinned chemically and/or mechanically, for example.

In a next method step, a plurality of first laser chips are applied laterally between each second laser chip and each third laser chip on the side of the connection carrier plate facing away from the second laser chips and third laser chips. The first laser chips can be mechanically attached and electrically connected to the connection carrier plate.

In a further method step, the laser is divided into individual laser components, each comprising a first laser chip, a second laser chip, a third laser chip, and a part of the connection carrier plate as a connection carrier. In the event that part of the module carrier plate remains in the laser component as a module carrier, the module carrier is also divided accordingly. However, it is also possible for the module carrier to be removed before the connection carrier plate is divided, thus serving as an auxiliary carrier during the production of the laser components without being divided itself.

According to at least one embodiment of the method, a metallization is applied on the side facing away from the second and third laser chips after the connection carrier plate has been thinned. This metallization can be used, for example, to form contacts for contacting the laser chips.

In the following, the laser component described herein and the method described herein for producing a laser component are explained in more detail with reference to exemplary embodiments and the associated figures.

### BRIEF DESCRIPTION OF THE DRAWINGS

FIGS. 1A, 1B and 1C show a first exemplary embodiment of a laser component described here by means of schematic representations.

The schematic representations in FIGS. 2A, 2B, 2C show a further exemplary embodiment of a laser component described here.

FIGS. 3A, 3B, 3C illustrate a further exemplary embodiment of a laser component described here in more detail by means of schematic representations.

With reference to the schematic representations of FIGS. 4A, 4B, 5A, 5B, 6A, 6B, an exemplary embodiment of a method described herein is explained in more detail.

### DETAILED DESCRIPTION

Elements that are identical, similar or have the same effect are marked with the same reference symbols in the figures. The figures and the proportions of the elements shown in the figures are not to be regarded as being to scale. Rather, individual elements may be shown in exaggerated size for better visualization and/or better comprehensibility.

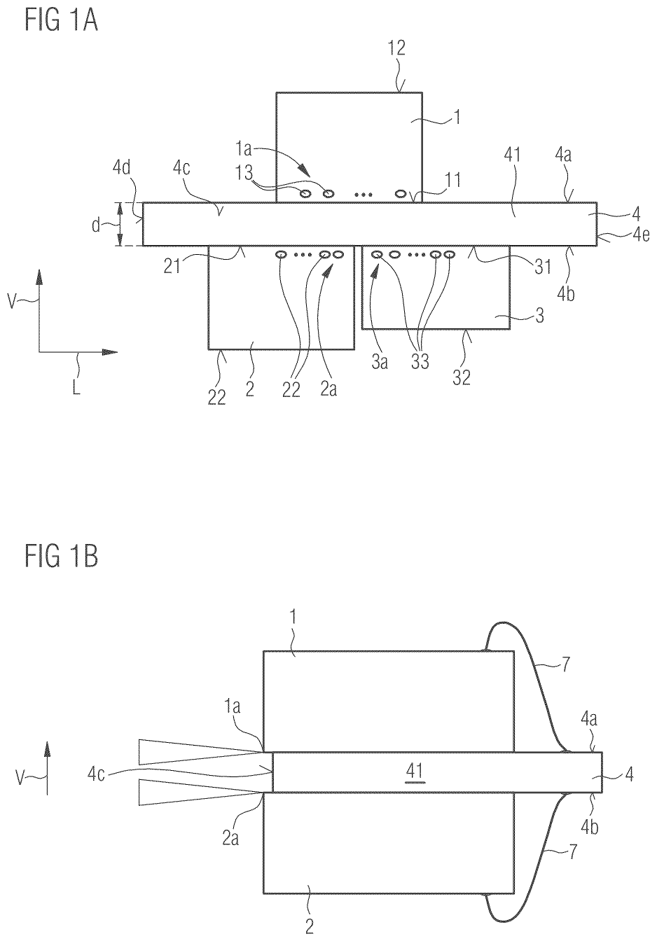

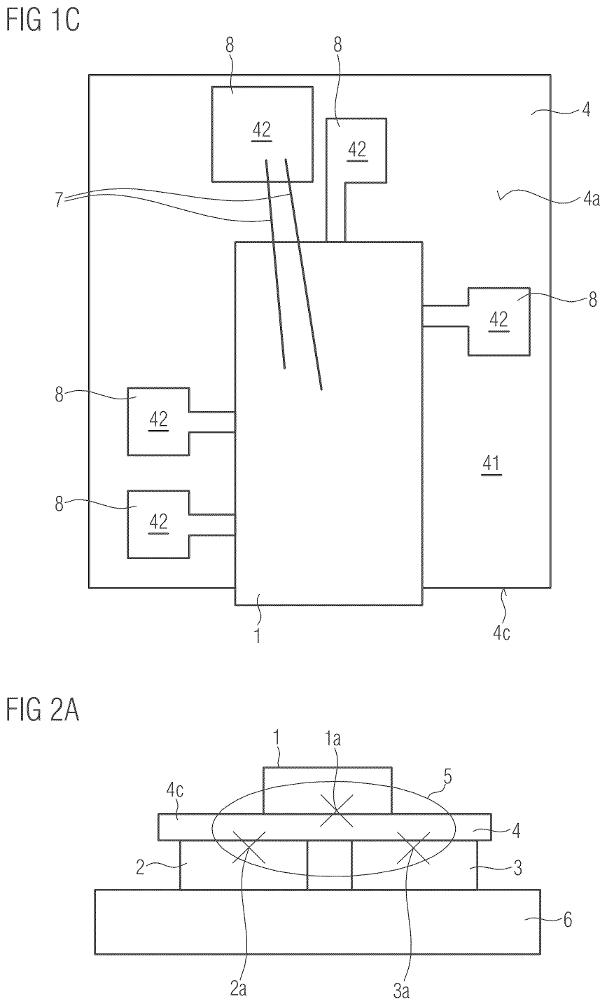

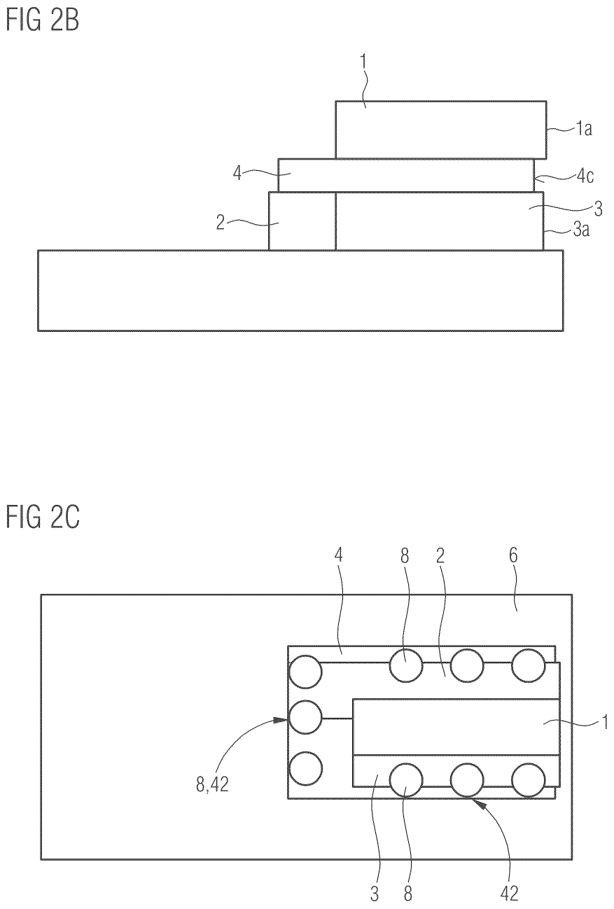

The schematic representation in FIGS. 1A, 1B and 1C illustrates in more detail a first exemplary embodiment of a laser component described here. FIG. 1A shows a side view of the exemplary embodiment from its front side. FIG. 1B shows a sectional view of the exemplary embodiment, and FIG. 1C shows a top view.

The laser component comprises a first laser chip 1 having a first emission region 1a. The first emission region 1a comprises a plurality of first emitters 13 arranged next to each other along a lateral direction L. The first laser chip 1 is an edge-emitting laser chip comprising a top surface 11 and a bottom surface 12. The emission region 1a is arranged closer to the top surface 11 than to the bottom surface 12.

The laser chip 1 is attached, for example soldered, to a connection carrier 4 at its top surface 11. The top surface 11 is, for example, the p-conducting side of the laser chip 1.

During operation, the laser chip 1 generates red light, for example.

The connection carrier 4 comprises an upper side 4a, to which the first laser chip 1 is attached and electrically connected. For example, a wire 7 is used to electrically connect the n-side at the bottom surface 12 of the first laser chip 1, see FIG. 1B. The connection carrier 4 comprises an electrically insulating base body as well as metallizations and contacts. The metallizations 42, which form contacts 8, are shown schematically, for example, on the upper side 4a of the connection carrier 4 in FIG. 1C.

The connection carrier has a thickness d in the vertical direction V which is at most 200 μm in the present case. The connection carrier 4 can be formed in particular with a ceramic material. It is also possible that the connection carrier 4 comprises a base body 41 formed with silicon or diamond. In this case, the thickness d of the connection carrier can be less than 150 μm, for example 120 μm or less.

The laser component further comprises a second laser chip 2 having a second emission region 2b. The second emission region 2b comprises a plurality of emitters 23, which are arranged next to each other in a lateral direction. The second laser chip generates, for example, blue light during operation.

Furthermore, the laser component comprises a third laser chip 3, which has a third emission region 3a. The third emission region 3a comprises a plurality of third emitters 33, which are also arranged next to each other in a lateral direction L. For example, first emitters 13, second emitters 23 and third emitters 33 are each arranged along straight lines that are parallel to each other within the manufacturing tolerance.

In the present case, the second laser chip 2 and the third laser chip 3 are arranged on the lower side 4b of the connection carrier 4, where they are mechanically attached and electrically connected. The second laser chip 2 and the third laser chip 3 are attached to the lower side 4b of the connection carrier 4 with their top surfaces 21, 31, which are each facing away from their bottom surfaces 22, 32. The top surface 21 of the second laser chip and the top surface 31 of the third laser chip 3 are located closer to the second emission region 2a and the third emission region 3a, respectively, than the respective bottom surfaces 22, 32.

The top surfaces 21, 31 are each located on the p-conducting side, for example, so that the second laser chip 2 and the third laser chip 3 are also mechanically attached and electrically connected to the connection carrier 4 with their p-side. As shown in FIG. 1B, the n-side at the bottom surface 22 or 32 can be contacted using a wire 7.

The second laser chip 2 and the third laser chip 3 are arranged next to each other in the lateral direction L on the lower side 4b of the connection carrier 4. The first laser chip 1 is arranged on the upper side 4a above the first laser chip 2 and the third laser chip 3 in such a way that it has an overlap with both laser chips in the vertical direction V. In this way, the three laser chips 1, 2, 3 can be mounted in a particularly space-saving and compact manner in the lateral direction. The lateral extension is therefore smaller than if the three laser chips 1, 2, 3 were arranged laterally next to each other.

Due to the particularly thin connection carrier 4 with its low thickness d and the mounting of the emission regions 1a, 2a, 3a facing the connection carrier 4, the distance in the lateral direction V between the emission regions 1a, 2a, 3a is also particularly small. In particular, the laser component is designed very compact in this way.

As shown in FIGS. 1A, 1B and 1C, the emission regions 1a, 2a, 3a are located on the front side 4c of the connection carrier 4, for example in a common plane. As shown in FIG. 1B, they can project beyond the connection carrier 4 in the lateral direction.

During operation, the laser chips 1, 2, 3 each generate laser radiation with different wavelengths in pairs. For example, the second laser chip 2 generates blue light during operation, and the third laser chip 3 generates green light during operation. The laser radiation is emitted from the emitters 13, 23, 33 in such a way that the fast axis of the laser radiation runs in the vertical direction V. Due to the small thickness of the connection carrier 4, it is therefore possible for the individual laser beams to overlap and mix even at a short distance from the laser component.

For the laser component of the exemplary embodiment of FIGS. 1A to 1C, it is possible, for example, that the connection carrier 4 is attached to side surfaces 4d, 4e in a housing and there is no other carrier for the laser chips. In this case, the connection carrier 4 is the only supporting element of the laser component. This enables a particularly compact design of the laser component.

In conjunction with the schematic illustrations in FIGS. 2A to 2C, a further exemplary embodiment of a laser component described here is explained in more detail. FIG. 2A shows a front view, FIG. 2B shows a side view, and FIG. 2C shows a top view.

In contrast to the exemplary embodiment of FIGS. 1A to 1C, the laser component in the exemplary embodiment of FIGS. 2A to 2C comprises a module carrier 6, to which two laser chips 2, 3 are mechanically attached and, if necessary, electrically connected. In this case, the second laser chip 2 and the third laser chip 3 must each have the same extension in the vertical direction V. This is not necessary for the exemplary embodiment of FIGS. 1A to 1C. On the other hand, the module carrier 6 provides the laser component with increased mechanical stability and improved heat dissipation.

The connection carrier 4 is again arranged between the first laser chip on the one hand and the second and third laser chips 2, 3 on the other hand and has a smaller lateral extension than the module carrier 6. Contacts 8 in the form of metallizations 42 for contacting all laser chips 1, 2, 3 of the laser component can be formed on and by the connection carrier 4. The laser component also has an optical system comprising at least one optical element 5 through which all light generated by the laser chips 1, 2, 3 during operation passes. The optical system comprises at least one optical element 5, which may be a lens, for example.

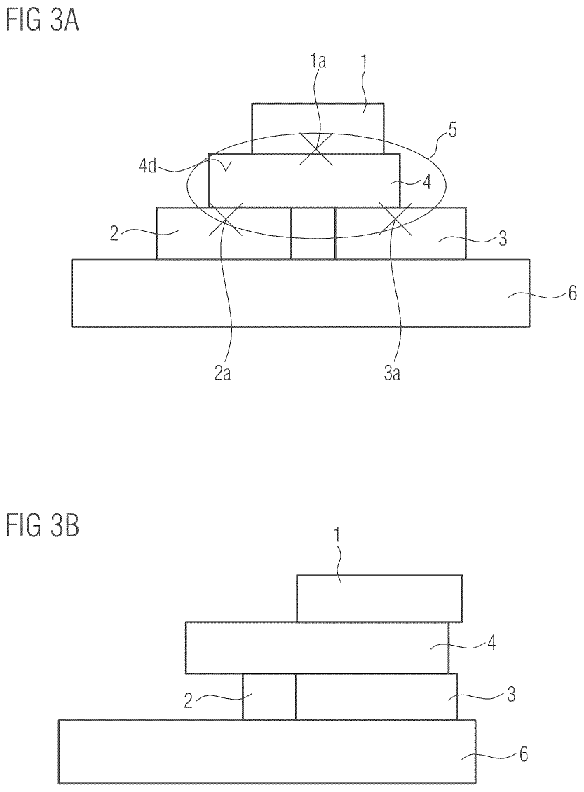

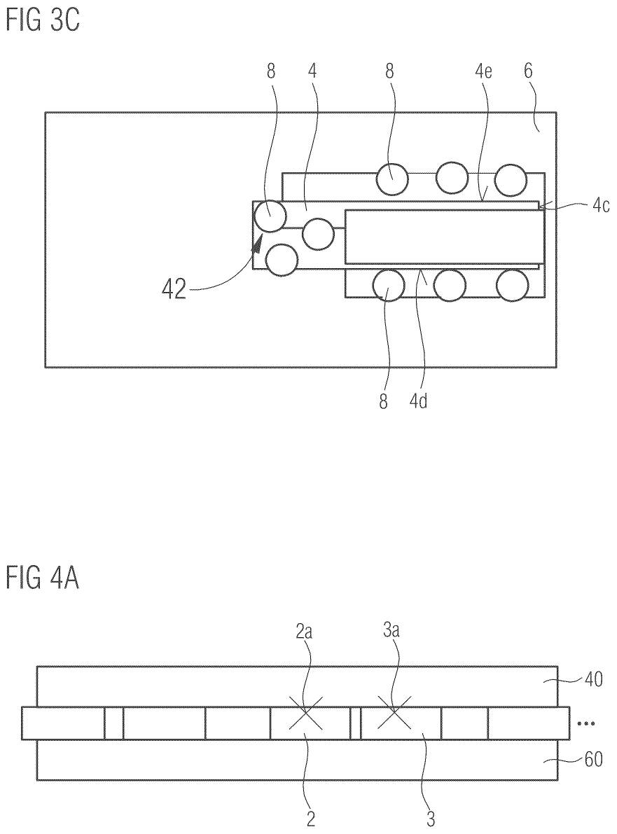

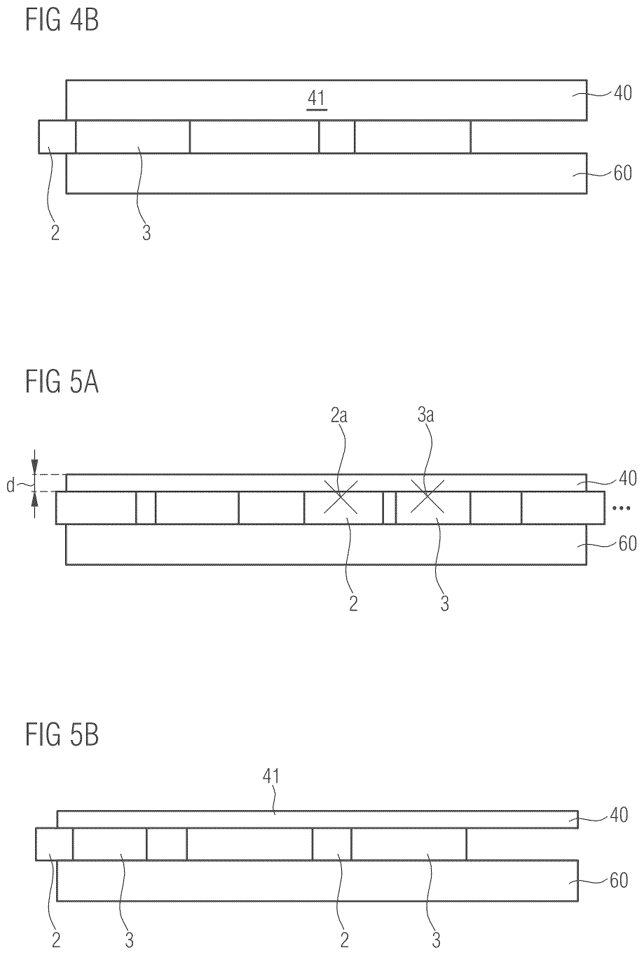

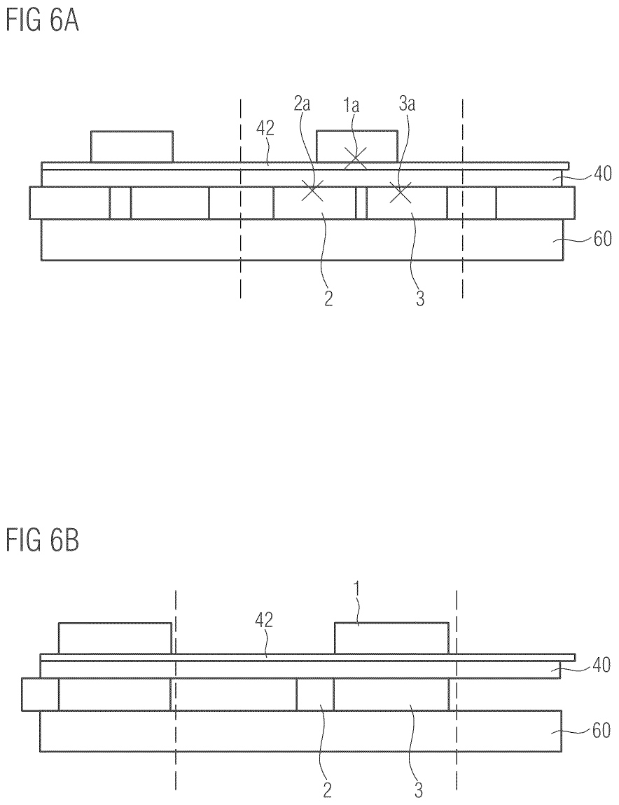

In conjunction with FIGS. 3A to 3C, a further exemplary embodiment of a laser component described here is explained in more detail. FIG. 3A shows a schematic front view. FIG. 3B shows a schematic side view, and FIG. 3C shows a schematic top view. In contrast to the exemplary embodiment of FIGS. 2A to 2C, the connection carrier 4 is designed with a smaller surface area in this exemplary embodiment. As a result, the second laser chip 2 and the third laser chip 3 on the lower side 4b of the connection carrier 4 protrude laterally beyond the connection carrier 4. This means that the second laser chip 2 projects laterally beyond the side surface 4d in the lateral direction L, and the third laser chip 3 projects laterally beyond the side surface 4e in the lateral direction. This means that the connection carrier 4 is particularly small, so that the connection carrier can be formed using expensive materials such as diamond without increasing the cost of the laser component too much. These expensive materials can be characterized by particularly high heat conductivity.

Heat dissipation for the laser chips 2, 3, which are arranged on the module carrier 6, is achieved, for example, by a particularly large-area connection between these laser chips and the module carrier 6.

In the exemplary embodiment shown here, it is also possible that the first laser chip 1 is the laser chip that generates blue light during operation. In particular in the exemplary embodiments shown in FIGS. 2 and 3, the laser chip emitting red light is then arranged in contact with the module carrier 6. In this way, heat generated during operation can be dissipated particularly well, which proves to be particularly advantageous for the laser chip that emits red light, as the wavelength of the generated light is highly temperature-dependent for this laser chip.

The module carrier 6 may, for example, be a carrier formed with a ceramic material such as AlN or SiC. The module carrier 6 can be designed as a connection carrier and comprise electrical contacts and/or circuit boards for contacting at least some of the laser chips 1, 2, 3. In particular, the module carrier 6 may have a greater thickness in the vertical direction than the connection carrier 4.

In connection with the schematic sectional views of FIGS. 4A, 4B, 5A, 5B, 6A and 6B, an exemplary embodiment of a method described herein is explained in more detail. FIGS. 4A, 5A, 6A show a front view of the emission side of the laser chips 1, 2, 3. FIGS. 4B, 5B, 6B show the corresponding side view.

In the method, a module carrier plate 60 is first provided, which can be formed with a ceramic material, for example. Second laser chips 2 and third laser chips 3 are then alternately applied on the module carrier plate 60. In a next method step, a connection carrier plate 40 is applied on the second laser chips 2 and the third laser chips 3 on their side facing away from the module carrier plate 60. For example, the laser chips 2, 3 can be connected to the module carrier plate and/or the connection carrier plate by adhesion, soldering or direct bonding.

This results in the arrangement shown in FIGS. 4A and 4B, consisting of module carrier plate 60 and connection carrier plate 40 with second and third laser chips 2, 3 inserted in between. The lateral extension of the module carrier plate 60 and that of the connection carrier plate 40 can be the same. The connection carrier plate 40 and the module carrier plate 60 are then aligned plane-parallel to each other, for example.

In a next method step, FIGS. 5A, 5B, the connection carrier plate 40 can be thinned to a target thickness of at most 200 μm. If the module carrier plate 40 is formed with a ceramic material, for example if it has a ceramic base body 41, it is thinned to a thickness of at least 150 μm. If the module carrier plate 40 is made of a semiconductor material such as silicon or diamond, it can be thinned to a thickness of less than 150 μm, for example to less than 120 μm or less than 100 μm. The module carrier plate 40 can already include vias in the base body 41, or these can be generated subsequently.

In the next method step, FIGS. 6A, 6B, a metallization 42 can be applied to the module carrier plate 40. The metallization 42 can be used for contacting the laser diode chips.

In a next method step, first laser chips 1 are applied laterally between each second laser chip 2 and each third laser chip 3 on the side of the connection carrier plate 40 facing away from the second laser chips 2 and third laser chips 3.

In a further method step, the system can be divided into individual laser components, each comprising a first laser chip 1, a second laser chip 2 and a third laser chip 3 as well as a part of the connection carrier plate 40. The part of the connection carrier plate 40 then forms the connection carrier 4. In this way, a plurality of laser components can be produced in a single process.

The invention is not limited to the exemplary embodiments by the description based on these embodiments. Rather, the invention includes any new feature as well as any combination of features, which includes in particular any combination of features in the patent claims, even if this feature or combination itself is not explicitly stated in the patent claims or exemplary embodiments.

1. A laser component comprising:
a first laser chip having a first emission region,
a second laser chip having a second emission region, and
a connection carrier having an upper side and a lower side, wherein
the first laser chip is attached and electrically connected to the upper side of the connection carrier,
the second laser chip is attached and electrically connected to the lower side of the connection carrier, and
the connection carrier has a thickness of at most 200 μm.

2. The laser component according to claim 1, further comprising
a third laser chip having a third emission region (3a), wherein
the third laser chip is attached and electrically connected to the upper side (4a) or the lower side of the connection carrier.

3. The laser component according to claim 1, further comprising
at least one further laser chip having at least one further emission region, wherein
the at least one further laser chip is attached and electrically connected to the upper side or the lower side of the connection carrier.

4. The laser component according to claim 1, in which the light emitted by the laser chips during operation can be mixed to form white light.

5. The laser component according to claim 1, in which the first, second and third laser chips are each attached to the connection carrier at their respective top surface, with the first, second and third emission regions being arranged closer to the respective top surface than to the bottom surface opposite the top surface.

6. The laser component according to claim 1, in which the connection carrier comprises glass, ceramic material, plastic, silicon and/or diamond.

7. The laser component according to claim 1, in which the first, second and third emission regions are each arranged on a front side of the connection carrier.

8. The laser component according to claim 1, in which two of the laser chips protrude laterally beyond the connection carrier.

9. The laser component according to claim 1, in which an optical element is arranged downstream of the first, second and third laser chips in such a way that the light generated during operation passes through the optical element in each case.

10. The laser component according to claim 1, further comprising a module carrier, to which two of the laser chips are attached on their side facing away from the connection carrier.

11. The laser component according to claim 1, in which the connection carrier is the only supporting element of the laser component.

12. A method for producing a laser component, comprising:
providing a module carrier plate,
applying second laser chips and third laser chips on the module carrier plate,
applying a connection carrier plate on the second laser chips and third laser chips on their side facing away from the module carrier plate,
thinning the connection carrier plate,
applying first laser chips laterally between each second laser chip and each third laser chip on the side of the connection carrier plate facing away from the second laser chips and third laser chips, and
dividing into individual laser components each comprising a first laser chip, a second laser chip, a third laser chip, and a part of the connection carrier plate as a connection carrier.

13. The method according to claim 1, in which a metallization is applied on the side facing away from the second and third laser chips after the connection carrier plate has been thinned.

14. The method according to claim 12, in which a laser component is produced comprising,
a first laser chip having a first emission region,
a second laser chip having a second emission region, and
a connection carrier having an upper side and a lower side, wherein
the first laser chip is attached and electrically connected to the upper side of the connection carrier,
the second laser chip is attached and electrically connected to the lower side of the connection carrier, and
the connection carrier has a thickness of at most 200 μm.
